(19) United States
(12) Patent Application Publication
(10) Pub. No.: US 2009/0195273 A1
(43) Pub. Date: Aug. 6, 2009

(54) START-UP CIRCUIT FOR SMIA INPUT CLOCK BUFFER

(75) Inventor: Yan Lee, Guildford (GB)

Correspondence Address: RatnerPrestia, P.O. BOX 980, VALLEY FORGE, PA, 19482, US

(73) Assignee: MICRON TECHNOLOGY, INC., Boise, ID (US)

(21) Appl. No.: 12/026,641

(22) Filed: Feb. 6, 2008

(51) Int. Cl. H03K 17/22

(52) U.S. Cl. 327/143; 327/142

(57) ABSTRACT

A circuit for a buffer includes input and output nodes, in which the buffer provides a high level voltage output at the output node for a low level input leakage condition at the input node. The circuit includes a pull-up circuit, coupled to the input node, for providing a pull-up voltage to raise a common voltage level of an input signal. The buffer includes a transistor coupled to the input node, in which the transistor is turned on, in response to the pull-up voltage. A detector is coupled to the output node for detecting presence of the input signal. Upon the transistor turning on, the output node provides a buffered output signal corresponding to the input signal, and upon the detector detecting the presence of the input signal, the pull-up circuit is configured to remove the pull-up voltage. The input signal is an AC coupled signal having a peak-to-peak voltage excursion about a common DC voltage value. The input signal is an AC coupled clock signal adopted for standard mobile architecture (SMIA).

### TECHNICAL FIELD

The present invention relates, in general, to imaging devices. More specifically, the present invention relates to speeding up performance of a buffer configured to deliver a clock signal to circuits used by imaging devices.

### BACKGROUND OF THE INVENTION

A standard mobile imaging architecture (SMIA) is being adopted in CMOS imaging and other camera related applications. Sensors and system-on-a-chip (SOC) designs, therefore, are advantageously required to be SMIA compatible.

As an example, a buffer may be used to provide a clock signal to various circuits of imaging devices. The buffer may receive an external clock signal that is DC coupled to the buffer or AC coupled to the buffer.

The characteristics of external clocks, with which an SMIA clock buffer is required to be compatible, is listed in the following table:

SMIA external clock input

Range

| External Clock | Min | Typical | Max | Unit |
|---|---|---|---|---|
| DC coupled square wave | 1.0 | 1.8 | 2.9 | V |
| AC coupled sine wave | 0.5 | 1 | 1.2 | Vp-p |
| Frequency | 6 | | 27 | MHz |
| Duty cycle | 45 | | 55 | % |
| Input leakage | −10 | | 10 | uA |

The input impedance of the SMIA clock buffer has to be high for low input leakage during DC coupled input conditions. As a result, a delay between application of the AC coupled clock at the input node of the SMIA clock buffer and the appearance of the clock signal at an output node of the SMIA clock buffer is in the region of tens of microseconds. This delay restricts choices of external capacitor values between the external clock signal and the input node of the SMIA clock buffer.

As will be explained, the present invention provides a speed-up circuit coupled to a clock buffer for lessening the delay between (a) the time of application of an AC coupled clock signal at the input node of the buffer and (b) the time of appearance of the clock signal at the output node of the clock buffer.

### BRIEF DESCRIPTION OF THE DRAWINGS

FIG. 1 is a schematic diagram of a system including a clock buffer with a start-up circuit, in accordance to an embodiment of the present invention.

FIG. 2 depicts several waveforms that are generated at different nodes of the system shown in FIG. 1, in accordance with an embodiment of the present invention.

### DETAILED DESCRIPTION OF THE INVENTION

The present invention includes a circuit for a buffer, in which the buffer is configured to provide a high level voltage output at an output node of the buffer for a low level input leakage condition existing at an input node of the buffer. The circuit includes a pull-up circuit, coupled to the input node of the buffer, for providing a pull-up voltage to raise a common voltage level of an input signal. The buffer includes a transistor coupled to the input node, in which the transistor is turned on, in response to the pull-up voltage. A detector circuit is coupled to the output node for detecting presence of the input signal. Upon the transistor turning on, the output node provides a buffered output signal corresponding to the input signal. Upon the detector detecting the presence of the input signal, the pull-up circuit is configured to remove the pull-up voltage.

As will be explained, the input signal is an AC coupled signal having a peak-to-peak voltage excursion about a common DC voltage value. An end of a capacitor is connected to the input node, and another end of the capacitor is configured to receive the input signal. The input signal is an AC coupled clock signal adopted for standard mobile imaging architecture (SMIA).

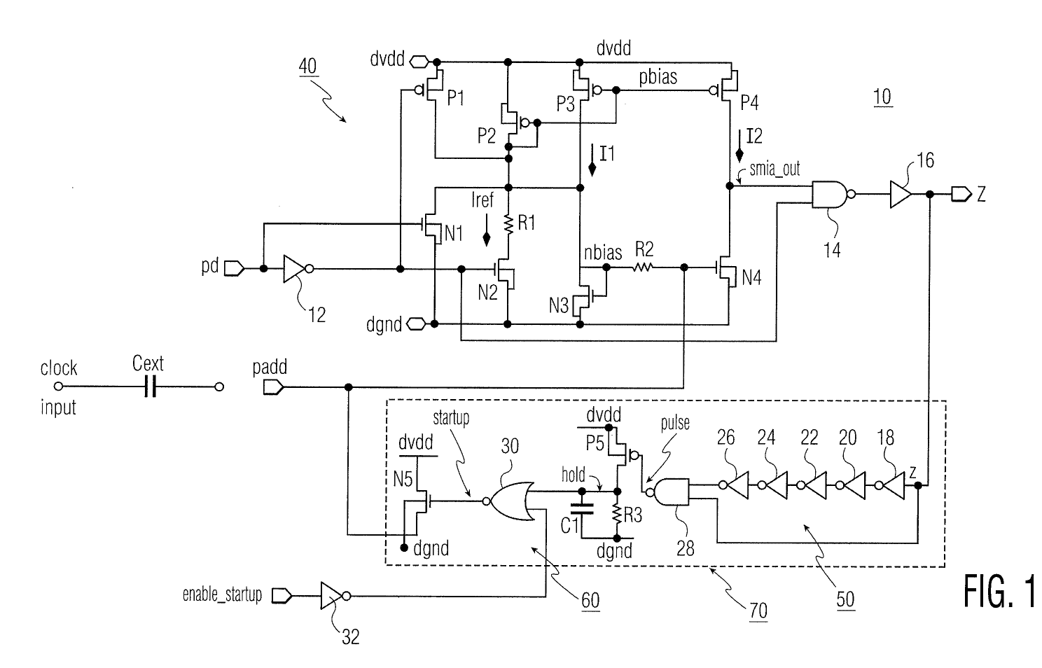

FIG. 1 depicts a system, generally designated as 10, including clock buffer 40, detector circuit 50 and pull-up circuit 60. The detector circuit 50 and pull-up circuit 60 together are defined herein as a start-up circuit, generally designated as 70. Clock buffer 40 includes an input node, designated by padd and an output node designated by Z.

As shown, the PMOS P4 and NMOS N4 transistors provide amplification for a clock signal inputted at the input node padd. An output signal of the amplifier, which is provided at a node of the serially coupled P4 and N4 transistors, is designated as smia_out. The smia_out signal is provided as an input signal to NAND-gate 14. Accordingly, when the N4 transistor is off, the P4 transistor provides a level one signal (dvdd) to NAND-gate 14. When the N4 transistor, however, is fully turned on, the smia_out signal is at a ground potential (dgnd). The output signal from NAND-gate 14 is buffered by buffer 16 (non-inverter) to provide an output signal at the output node Z.

The clock buffer 40 of system 10 is comprised of PMOS transistors P1, P2, P3 and P4; NMOS transistors N1, N2, N3 and N4; resistors R1 and R2; NAND-gate 14; buffer 16 and inverter 12. The detector circuit 50 is comprised of inverters 18, 20, 22, 24, and 26 and NAND-gate 28. The pull-up circuit, designated by 60, is comprised of PMOS transistor P5, NMOS transistor N5, resistor R3, capacitor C1, NOR-gate 30 and inverter 32.

For purpose of explanation, a clock input signal is shown provided at one end of an external capacitor, designated by Cext. The other end of external capacitor Cext is connected to the input node padd of clock buffer 40. The input node padd is driven by an AC coupled clock signal via the external capacitor Cext.

This clock signal is amplified by a constant current inverting amplifier comprising NMOS N4 and PMOS P4 transistors. The PMOS P4 transistor provides a constant current source with its gate biased by a reference voltage, designated as pbias, which is generated at the pbias node by the PMOS P2 transistor and resister R1. The constant reference current Iref is set by the value of resistor R1 and the voltage potential between the pbias node and the ground reference dgnd.

The currents I1 and I2 are set by the aspect ratio of the PMOS P3 and PMOS P4 transistors to the PMOS P2 transistor, e.g.:

I1=2*Iref,
if W/L of P3 is twice the W/L of P2.

The PMOS P3 and NMOS N3 transistors set up the biasing voltage, nbias, at the nbias node for the NMOS N4 transistor via resistor R2. The amplified signal is further enhanced by NAND-gate 14 and buffer 16.

Power down is provided by NMOS N1, NMOS N2, PMOS P1, NAND-gate 14 and inverter 12. During power down, the pd node is raised to the dvdd potential from the ground reference of dgnd. As a result, the output signal of NAND-gate 14 is forced high and the output node of clock buffer 40, Z, is also forced high.

To minimize leakage current, the PMOS P1 transistor connects the pbias node to the dvdd potential, while the NMOS N1 transistor connects the nbias node to the ground reference. In addition, the NMOS N2 transistor, which is turned off, disconnects the R1 resistor from the ground reference.

As described above, the external AC coupled clock signal is fed to clock buffer 40 via the external capacitor Cext. This clock signal is amplified by the NMOS N4 and PMOS P4 transistors. The NMOS N4 transistor is biased in its saturation operating point by the biasing circuit of the PMOS P3, NMOS N3 transistors and resistor R2. To set-up the correct biasing level, the aspect ratios of the P4 and N4 transistors to the P3 and N3 transistors are matched. The R2 resistor provides a high impedance input at the input node of buffer 40. The PMOS P2 transistor and resistor R1 form a constant current source biasing circuit.

The biasing voltage at the gate of the NMOS N4 transistor is determined by the RC time constant of resistor R2 and capacitor Cext. As an example, for R2=500K ohms and Cext=10 pF, the rise time of an input clock pulse is in the region of 20 uS. The only parameter that may be changed to improve the rise time is Cext, because R2 has to be in the region of 500 k ohms in order to limit the input leakage current at the input node padd. It will be appreciated that the input capacitance of a bond pad is approximately 2 pF. Any reduction of the value of Cext, therefore, attenuates the input signal further and may impact the SMIA input clock buffer performance.

Initially, during a normal operation with the pd node at ground reference, there is no signal applied to the input node padd, and the gate of the NMOS N4 transistor is at ground potential. The drain of the NMOS N4 transistor is pulled up to the dvdd potential by the I2 current. In turn, the output of NAND-gate 14 is at a logic low and the clock buffer output node Z is at a logic low.

With Z at a logic low, the pulse node of detector circuit 50, at NAND-gate 28, is at a logic high. As a result, the PMOS P5 transistor is off and the hold node, at the output of the PMOS P5 transistor is at a ground reference dgnd.

With the enable_startup node of pull-up circuit 60 at a logic high, the output of inverter 32 is at a logic low. Therefore, the output of NOR-gate 30, the startup node, is at a logic high of dvdd. As a result, the NMOS N5 transistor, which is turned on, forces the input node padd to rise to a level of:
dvdd-Vthn5,
where Vthn5 is the threshold voltage of the NMOS N5 transistor.
   It will be appreciated that using an NMOS transistor instead of a PMOS transistor helps maintain the gate of the NMOS N4 transistor around its switching threshold, at times when the input node padd is not being driven by an input clock signal.

When an AC coupled clock signal is applied to clock buffer 40, the signal appears at input node padd and the gate of the NMOS N4 transistor by way of capacitor Cext. Initially, when the amplitude of the clock signal at the input node padd is less than the threshold of the NMOS N4 transistor, the smia_out node remains high. As the common mode voltage at the input node padd rises, the NMOS N4 transistor begins to turn on and to pull down the smia_node toward a ground reference. The output node Z of buffer 40 goes from a low level to a high level.

With the output node Z going to a high level, a negative going pulse is generated by detector circuit 50 at the pulse node. The PMOS P5 transistor is turned on for the duration of the pulse, which in turn charges capacitor C1 toward the dvdd potential. As more and more pulses are generated, the hold node reaches a higher voltage level than the input switching threshold of NOR-gate 30 and the NMOS N5 transistor is turned off. At this time, the common mode voltage at the gate of the NMOS N4 transistor is maintained by the incoming AC coupled clock signal.

If the input clock signal is stopped, however, no more pulses are generated by detector circuit 50 and the PMOS P5 transistor is turned off. The voltage at the hold node at the input of NOR-gate 30 begins to fall, as the C1 capacitor is discharged by resistor R3. When the hold node drops below the switching threshold of NOR-gate 30, the startup node at the input gate of the NMOS N5 transistor goes from a ground reference to the dvdd potential. As a result, the NMOS N5 transistor is switched on and holds the input node padd at the dvdd-Vthn5 potential. When the input clock signal resumes, the preferred switching threshold of the NMOS N4 transistor may be established quickly.

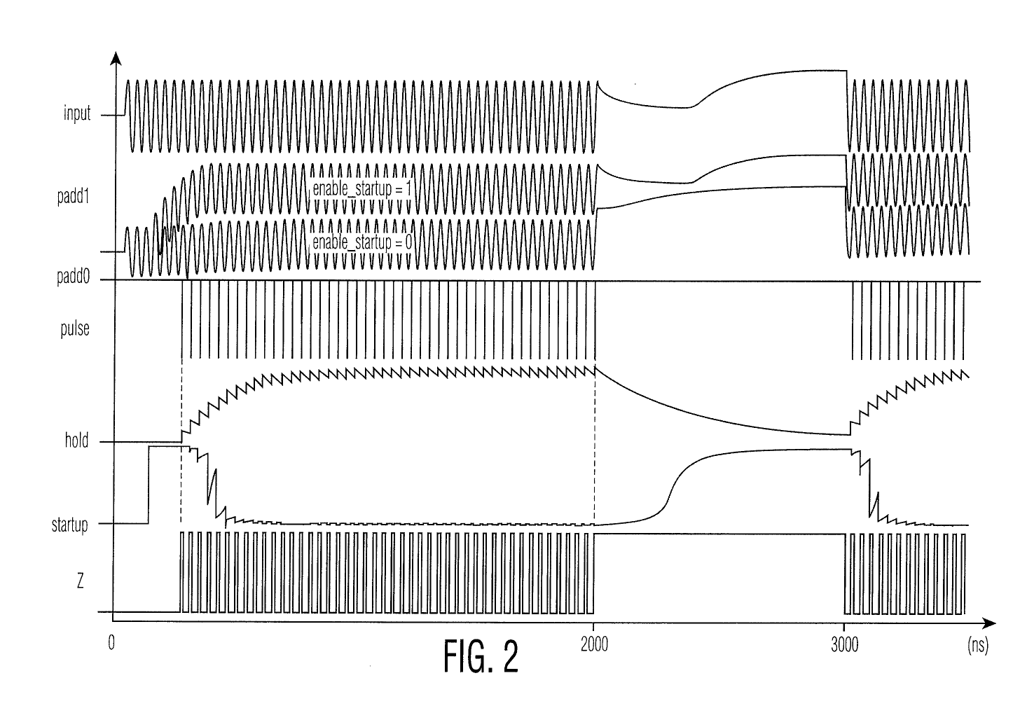

The output signal waveforms at various nodes of system 10 are shown in FIG. 2. The input clock signal, shown at the top of the figure, is started at time zero, then stopped at time 2000 nsec (approximately), and restarted at time 3000 nsec (approximately). Also shown in FIG. 2 is the signal waveform at the input node padd with the start-up enabled at inverter 32 (enable_startup=1) and with the start-up disabled at inverter 32 (enable_startup=0).

Also shown in FIG. 2 are the pulses generated by detector circuit 50 at the pulse node, the waveform generated at the hold node, and the waveform generated at the startup node, all in response to the input clock signal. Also shown is the waveform generated at the output node Z which is similar to the input clock signal.

As shown, when the enable_startup is disabled, the common mode voltage at the input node of buffer 40 builds up very slowly toward the switching threshold of the NMOS N4 transistor. However, when the enable_startup is enabled, the common mode voltage at the input node of buffer 40 builds up very quickly toward the switching threshold of the NMOS N4 transistor, thereby reducing the delay between the clock input signal at the padd node and the clock output signal at the Z node.

The present invention thus provides an input clock buffer with a start-up circuit which has several advantages over any conventional buffers. It provides a start-up response time of a few clock cycles, instead of tens of microseconds. It also allows the use of a much higher value of an external capacitor Cext that may be used to improve performance of the buffer, the latter due to less amplitude attenuation of the input signal.

It will be understood that system 10 shown in FIG. 1 may be used to buffer signals other than clock signals. The present invention is thus not intended to be limited to a clock buffer.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A circuit for a buffer having input and output nodes, in which the buffer provides a high level voltage output at the output node for a low level input leakage condition at the input node, comprising
a pull-up circuit, coupled to the input node, for providing a pull-up voltage to raise a common voltage level of an input signal,
the buffer including a transistor coupled to the input node, in which the transistor is turned on, in response to the pull-up voltage, and
a detector, coupled to the output node, for detecting presence of the input signal,
wherein upon the transistor turning on, the output node provides a buffered output signal corresponding to the input signal, and
upon the detector detecting the presence of the input signal, the pull-up circuit is configured to remove the pull-up voltage.

2. The circuit of claim 1, wherein
the input signal is an AC coupled signal having a peak-to-peak voltage excursion about a common DC voltage value.

3. The circuit of claim 1, wherein
an end of a capacitor is connected to the input node, and
another end of the capacitor is configured to receive the input signal.

4. The circuit of claim 1, wherein
the input signal is an AC coupled clock signal adopted for standard mobile imaging architecture (SMIA).

5. The circuit of claim 1, wherein
the transistor includes a gate connected to the input node, and
presence of the pull-up voltage at the input node is effective to turn on the transistor.

6. The circuit of claim 1, wherein
the detector includes a delay circuit coupled to the output node, for providing a predetermined delay time, and
the pull-up circuit is configured to remove the pull-up voltage after the predetermined delay time.

7. The circuit of claim 1, wherein
the transistor includes a gate connected to the input node, and
the transistor is biased to turn on when a low level leakage voltage is present at the gate.

8. The circuit of claim 7, wherein
a series connected PMOS and NMOS transistors are configured to provide a bias voltage for biasing the gate of the transistor.

9. The circuit of claim 1, wherein
the buffer includes an amplifier disposed between the input and output nodes, and
the transistor is part of the amplifier.

10. The circuit of claim 1, wherein
the pull-up circuit includes a logic-gate configured for
providing the pull-up voltage when an enable startup command is present, and
removing the pull-up voltage when the detector detects presence of the input signal for a predetermined time length.

11. A buffer providing signal amplification between input and output nodes comprising
serially coupled NMOS and PMOS transistors having a gate directly connected to the input node and a drain coupled to the output node for providing signal amplification, and
a pull-up circuit connected directly to the input node for providing a pull-up voltage to an input signal,
wherein the pull-up voltage raises a common voltage level of the input signal, and
presence of the raised common voltage level of the input signal at the gate turns on the NMOS transistor for providing amplification to the input signal.

12. The buffer of claim 11, wherein
the NMOS transistor is biased to have a saturated operating point, and
the NMOS transistor is turned on for providing a high level output voltage, when a low level input leakage condition is present at the gate.

13. The buffer of claim 11, wherein
one end of a capacitor is connected to the input node, and
another end of the capacitor is configured to receive the input signal.

14. The buffer of claim 11, including
a detector connected to the output node for detecting presence of an AC input signal,
the detector including a delay circuit for providing a predetermined delay time signal, upon detection of the AC input signal, and
the pull-up circuit receiving the predetermined delay time signal and disabling the pull-up voltage.

15. The buffer of claim 14, wherein the pull-up circuit includes
a logic-OR gate for enabling and disabling the pull-up voltage, and
the logic-OR gate having first and second input terminals,
wherein the first input terminal provides the predetermined delay time signal for disabling the pull-up voltage, and
the second input terminal provides an enable startup control for enabling the pull-up voltage.

16. A start-up circuit for an imaging sensor comprising
a buffer for transitioning an input clock signal between input and output nodes and providing, at the output node, an output clock signal to the imaging sensor, and
a pull-up circuit coupled to the input node of the buffer for raising a common voltage level of the input clock signal,
wherein when the pull-up circuit raises the common voltage level of the input clock signal, a transitioning delay time between the input clock signal and the output clock signal is smaller than when the pull-up circuit does not raise the common voltage level of the input clock signal.

17. The start-up circuit of claim 16 wherein
the buffer includes a transistor having a gate coupled to the input node, and
when the pull-up circuit raises the common voltage level of the input clock signal, the transistor enables the buffer to provide the output clock signal in response to the input clock signal.

18. The start-up circuit of claim 16 wherein
one end of a capacitor is connected to the input node, and
another end of the capacitor is configured to receive the input clock signal.

19. The start-up circuit of claim 16 wherein
the buffer includes an amplifier for amplifying the input clock signal and providing an amplified output clock signal.

20. The start-up circuit of claim 16 wherein
the buffer includes a power-down circuit for disabling the output clock signal at the output node.

21. The start-up circuit of claim 16 including
a detector coupled to the output node for detecting presence of the input clock signal, and
the detector providing a control signal for disabling the pull-up circuit from raising the common voltage level of the input clock signal after a predetermined time interval.

22. In a buffer providing a buffered output signal in response to an input signal, a start-up circuit comprising
a detector coupled to an output node of the buffer for detecting presence of the buffered output signal, and providing a disable start-up command, after a predetermined time interval,
a logic OR-gate having first and second input terminals and an output terminal, the output terminal coupled to an input node of the buffer for superpositioning a DC voltage level onto the input signal, and
the first input terminal coupled to an enable start-up command and the second input terminal coupled to the disable start-up command,
wherein the enable start-up command is provided to the first input terminal for enabling the superpositioning of the DC voltage level onto the input signal, and
the disable start-up command is provided to the second input terminal for disabling the superpositioning of the DC voltage level onto the input signal,
wherein the superpositioning of the DC voltage level onto the input signal is effective in speeding up a transitioning time of the input signal through the buffer to provide the output signal.

23. A start-up circuit of claim 22 wherein
the detector includes a plurality of inverters configured to provide the predetermined time interval for providing the disable start-up command.

24. A start-up circuit of claim 22 wherein
the input signal is an AC coupled clock signal.

25. A start-up circuit of claim 22 wherein
the buffer includes a transistor for enabling and disabling a path of the input signal through the buffer to provide the output signal, and
the superpositioning of the DC voltage level onto the input signal is configured to switch the transistor on and enable the path to provide the output signal.
